(19) United States
(12) Patent Application Publication
(10) Pub. No.: US 2022/0310981 A1
(43) Pub. Date: Sep. 29, 2022

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Letao Zhang, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/056,748

(22) PCT Filed: Aug. 31, 2020
(86) PCT No.: PCT/CN2020/112435

§ 371 Date: Nov. 18, 2020

(30) Foreign Application Priority Data
Jul. 7, 2020 (CN) 202010646101.1

(51) Int. Cl. H01L 51/56; H01L 27/32; H01L 51/52

(52) U.S. Cl. CPC H01L 51/56; H01L 27/3276; H01L 51/5218; H01L 2227/323

(57) ABSTRACT

The embodiments of the present disclosure provide a manufacturing method of a display panel and the display panel. The display panel includes a display area and a non-display area. When forming electrode layers of the display panel, a halftone mask process is performed on respective electrode layers, and a heat treatment is performed on the electrode layers in the non-display area to crystallize the electrode layers. Therefore, adhesion effect between the electrode layers and a substrate are enhanced and improved. The manufacturing method of the embodiments of the present disclosure is simpler and more effective, and the adhesion effect between electrode layers and the substrate is better.

### FIELD OF INVENTION

The present disclosure relates to the field of panel display technology, in particular to a display panel and a manufacturing method thereof.

### BACKGROUND OF INVENTION

With continuous development of display technology, various display devices have put forward higher and higher requirement on size and performance of display panels.

Wherein, active-matrix organic light-emitting diode (AMOLED) technology is a development trend of panel industry. Compared with liquid crystal displays (LCDs), OLEDs have advantages of simplified structure, wider color gamut and faster response times, etc. Currently, bottom-emitting type WOLEDs are the most widely used and are usually manufactured through evaporation methods. However, such manufacturing process is extremely wasteful of light-emitting materials, and aperture ratios of the devices are low, which go against application of high resolution display devices. Meanwhile, for top-emitting type OLEDs manufactured by existing processes, photomasks are used several times during manufacturing, and the processes are complicated, which are not conducive to improvement of overall performance of display panels.

Therefore, it is necessary to propose technical solutions to solve technical problems in the prior art.

### Technical Problem

In summary, in existing display panels and manufacturing process technology thereof, the waste of organic light-emitting materials is serious, and aperture ratios of the devices are low. Meanwhile, there are also problems such as too many photoetching times and complicated manufacturing processes, which are not conducive to improvement of overall performance of display devices.

### SUMMARY OF INVENTION

To solve the above problems, embodiments of the present disclosure provides a display panel and a manufacturing method thereof to solve problems such as serious waste of organic light-emitting materials, low apertures of devices and complicated manufacturing processes in existing display devices.

To solve the above technical problems, embodiments of the present disclosure provides the following technical solutions:

According to a first aspect of an embodiment of the present disclosure, a manufacturing method of a display panel is provided, which comprises the following steps:

S100: providing a substrate, depositing and patterning a passivation layer on a display area and a non-display area of the substrate;

S101: forming a planarization layer on the passivation layer, and patterning the passivation layer and the planarization layer;

S102: forming a composite anode film layer on the planarization layer and performing an etching process on the composite anode film layer, the composite anode film layer comprises a first electrode layer, a silver layer, and a second electrode layer disposed in sequence, wherein a halftone mask process is performed on the substrate corresponding to the non-display area;

S103: performing a heat treatment on the substrate in the non-display area, the heat treatment is performed under a temperature ranging from 100° C. to 150° C. and under protection of protecting gases to crystallize the composite anode film layer corresponding to the non-display area;

S104: peeling off redundant film layers of the composite anode film layer corresponding to the non-display area to obtain an electrode film layer;

S105: forming a pixel defining layer to obtain the display panel.

According to an embodiment of the present disclosure, the step S102 further comprises: performing a photoetching process on the substrate corresponding to the display area and the non-display area while using the halftone mask process.

According to an embodiment of the present disclosure, the mask corresponding to the non-display area is a semi-transmissive mask.

According to an embodiment of the present disclosure, when forming the composite anode film layer, the first electrode layer is disposed on the planarization layer.

According to an embodiment of the present disclosure, the first electrode layer electrically connects to thin film transistors and metal wires in the display panel through vias.

According to an embodiment of the present disclosure, in the step S100, when forming the passivation layer, a film layer on a side of the passivation layer away from the substrate is a SiNx film layer, and a thickness of the SiNx film layer ranges from 5 nm to 500 nm.

According to a second aspect of an embodiment of the present disclosure, a manufacturing method of a display panel is provided, which comprises the following steps:

S100: providing a substrate, depositing and patterning a passivation layer on a display area and a non-display area of the substrate;

S101: forming a planarization layer on the passivation layer, and patterning the passivation layer and the planarization layer;

S102: forming a composite anode film layer on the planarization layer and performing an etching process on the composite anode film layer, wherein a halftone mask process is performed on the substrate corresponding to the non-display area;

S103: performing a heat treatment on the substrate in the non-display area to crystallize the composite anode film layer corresponding to the non-display area;

S104: peeling off redundant film layers of the composite anode film layer corresponding to the non-display area to obtain an electrode film layer;

S105: forming a pixel defining layer to obtain the display panel.

According to an embodiment of the present disclosure, the step S102 further comprises: performing a photoetching process on the substrate corresponding to the display area and the non-display area while using the halftone mask process.

According to an embodiment of the present disclosure, the mask corresponding to the non-display area is a semi-transmissive mask.

According to an embodiment of the present disclosure, in the step S103, the treatment process comprises: the heat treatment is performed under a temperature ranging from 100° C. to 150° C. and under protection of protecting gases.

According to an embodiment of the present disclosure, when forming the composite anode film layer, the composite anode film layer comprises a first electrode layer, a silver layer, and a second electrode layer disposed in sequence, and the first electrode layer is disposed on the planarization layer.

According to an embodiment of the present disclosure, the first electrode layer electrically connects to thin film transistors and metal wires in the display panel through vias.

According to an embodiment of the present disclosure, in the step S100, when forming the passivation layer, a film layer on a side of the passivation layer away from the substrate is a SiNx film layer, and a thickness of the SiNx film layer ranges from 5 nm to 500 nm.

According to a third aspect of an embodiment of the present disclosure, a display panel is further provided and comprises:

a substrate;

a passivation layer disposed on the substrate;

a planarization layer disposed on the passivation layer corresponding to a display area; and

a pixel defining layer disposed on the passivation layer corresponding to the display area;

wherein the display panel further comprises a composite anode film layer and a first electrode layer, the composite anode film layer is disposed in pixel opening areas corresponding to the pixel defining layer, and the first electrode layer is disposed on the passivation layer corresponding to a non-display area, wherein the composite anode film layer electrically connects to thin film transistors through first vias, and the first electrode layer electrically connects to metal wires in the substrate through second vias.

According to an embodiment of the present disclosure, the composite anode film layer comprises an indium tin oxide film layer, a silver layer and a second electrode layer, and the silver layer is disposed on the indium tin oxide film layer.

According to an embodiment of the present disclosure, the first electrode layer comprises a crystallized indium tin oxide film layer.

According to an embodiment of the present disclosure, material of the passivation layer comprises SiO₂, SiNx, Al₂O₃.

According to an embodiment of the present disclosure, the material of the passivation layer is SiNx, and a thickness of the passivation layer ranges from 5 nm to 500 nm.

According to an embodiment of the present disclosure, the display panel further comprises metal wires, and the metal wires are disposed in the non-display area of the display panel.

According to an embodiment of the present disclosure, material of the metal wires comprises Mo, Al, Ti, Cu.

### BENEFICIAL EFFECT

To sum up, the beneficial effect of the embodiments of the present disclosure is:

The embodiments of the present disclosure provide a manufacturing method of a display panel and the display panel. The display panel comprises a display area and a binding region. When forming electrode layers or indium tin oxide layers of the display panel, the electrode layers corresponding to the display area and the binding region are formed while using a halftone mask process, in order to simplify the manufacturing process of the display panel. Further, a heat treatment is performed on the electrode layers in the binding region to crystalize the electrode layers and redundant film layers on the electrode layers to further removed to enhance and improve adhesion effect between the electrode layers and the substrate. The manufacturing method of the embodiment of the present disclosure is simpler and more effective, and the adhesion effect between electrode layers and the substrate in the display panel provided in the present embodiment is better and overall performance of the display panel is good.

### DESCRIPTION OF DRAWINGS

FIG. 1 is a schematic structural diagram of a display panel provided in an embodiment of the present disclosure,

FIG. 2 is a schematic structural diagram of film layers of the display panel provided in an embodiment of the present disclosure,

FIG. 3 is schematic flowchart of a manufacturing process of a display panel provided in an embodiment of the present disclosure,

FIG. 3A to FIG. 3C are schematic structural diagrams of film layers corresponding to a manufacturing method of a display panel provided in an embodiment of the present disclosure,

FIG. 4A to FIG. 4D are schematic flowcharts of manufacturing process of a composite anode film layer provided in an embodiment of the present disclosure,

FIG. 5 is a schematic diagram of crystallization of a first electrode layer provided in an embodiment of the present disclosure,

FIG. 6 is a schematic structural diagram of film layers of another display panel provided in an embodiment of the present disclosure.

### DETAILED DESCRIPTION OF PREFERRED EMBODIMENTS

Description of the following embodiments refers to the attached drawings to illustrate specific embodiments that the present disclosure can be implemented.

Display panels are widely used in various display devices. However, when manufacturing various kinds of display panels, especially when manufacturing an AMOLED panel, utilization rate of materials is often low, and more photomask processes are required during the manufacturing process, therefore the manufacturing process is complicated, which is not conducive to improvement of overall performance of the display panel and reduction of costs.

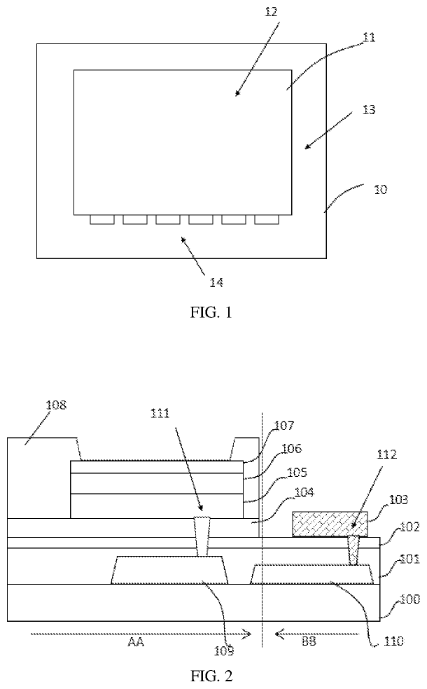

An embodiment of the present disclosure provides a display panel and a manufacturing method thereof to solve existing problems in the prior art. As shown in FIG. 1, FIG. 1 is a schematic structural diagram of a display panel provided in an embodiment of the present disclosure.

The display panel comprises a substrate 10 and an array substrate 11. The array substrate 11 is disposed on the substrate 10, wherein the substrate 10 may be a glass substrate or a flexible substrate, and the array substrate 11 may be a commonly used thin film transistor array substrate.

The display panel further comprises a display area 12 and a non-display area 13. In an embodiment of the present disclosure, the non-display area 13 is disposed around the display area 12. Meanwhile, the display area 13 further comprises a binding region 14. A plurality of connection terminals are disposed in the binding region 14, and parts of devices and wires are bounded to the array substrate 11 through the plurality of connection terminals.

Particularly, as shown in FIG. 2, FIG. 2 is a schematic structural diagram of film layers of a display panel provided in an embodiment of the present disclosure. The display panel comprises a display area AA and a non-display area BB. The display area AA may be adjacent to the non-display area BB and the non-display area BB is close to an edge of the display panel. In an embodiment of the present disclosure, the non-display area BB takes the binding region at the edge of the display panel as an example for description.

The display panel further comprises a substrate 100, a passivation layer 101, and an insulating layer 102. The passivation layer 101 is disposed on the substrate 100, and the insulating layer 102 is disposed on the passivation layer 101. In an embodiment of the present disclosure, material of the passivation layer 101 is preferably one of SiO2, SiNx, Al2O3, or multiple materials thereof. Wherein, the passivation layer 101 may be at least a single film layer structure, and the passivation layer 101 may be an insulating film layer manufactured through a plasma enhanced chemical vapor deposition method.

In addition, materials of the insulating layer 102 may be SiNx materials, and a thickness of the SiNx film layer may range from 5 nm to 500 nm.

In an embodiment of the present disclosure, the passivation layer 101 and the insulating layer 102 may be set as a single film layer, and when it is set as a single film layer, materials of an upper surface of the film layer is set as SiNx materials, and a thickness of the SiNx film layer ranges from 5 nm to 500 nm.

Specially, the display panel further comprises a thin film transistor device layer 109 and metal wire layer 110. Wherein, the thin film transistor device layer 109 is disposed in an area corresponding to the display area AA of the display panel, and the metal wire layer 110 is disposed in an area corresponding to the non-display area BB of the display panel. Meanwhile, the passivation layer 101 covers the thin film transistor device layer 109 and the metal wire layer 110.

Material of the metal wire layer 110 may comprise one or a combination of Mo, Al, Ti, and Cu.

Preferably, the display panel provided in an embodiment of the present disclosure further comprises a planarization layer 104. The planarization layer 104 is disposed on the insulating layer 102, and disposed in a position corresponding to the display area AA of the display panel.

In addition, the display panel further comprises a composite anode film layer. The composite anode film layer in the embodiment of the present disclosure comprises a plurality of film layers, specially, comprises a first electrode layer 105, a silver layer 106, and a second electrode layer 107.

The first electrode layer 105 is disposed on the planarization layer 104 corresponding to the display area AA of the display panel. Meanwhile, the composite anode film layer is disposed on a pixel-emitting opening area corresponding to the display area AA of the display panel. The silver layer 106 is disposed on the first electrode layer 105 and the second electrode layer 107 is disposed on the silver layer 106.

Wherein, materials of the first electrode layer 105 and materials of the second electrode layer 107 may be the same, preferably, may be an indium tin oxide electrode film layer.

The display device further comprises a third electrode layer 103. The third electrode layer 103 is disposed on film layers corresponding to the non-display area of the display panel. Specially, the third electrode layer 103 is disposed on the insulating layer 102.

In an embodiment of the present disclosure, the third electrode layer 103 and the first electrode layer 105 may be manufactured by a same electrode film layer. That is, a same film layer forms the first electrode layer 105 and the third electrode layer 103 in different areas respectively under action of different masks.

The first electrode layer 105, the second electrode layer 107, and the third electrode layer 103 may be manufactured by the same materials.

In addition, in an embodiment of the present disclosure, in order to improve adhesion performance between the third electrode layer 103 and the insulating layer 102 in the non-display area BB, a heat treatment is performed on the third electrode layer 103 to crystallize the materials of the third electrode layer 103.

Since crystal grains of the third electrode layer 103 after crystallization become finer, adhesion between the third electrode layer 103 and the insulating layer 102 is effectively improved, thereby improving the bonding effect. However, no corresponding heat treatment process is required on the first electrode layer 105.

Meanwhile, the display panel provided in an embodiment of the present disclosure further comprises a first via 111 and a second via 112. The first via 111 is defined in an area corresponding to the thin film transistor device layer 109 in the display area AA, and penetrates the passivation layer 101, the insulating layer 102, and the planarization layer 104.

The second via 112 is defined in film layers corresponding to the metal wire layer 110 in the non-display area BB of the display panel. At the same time, the second via 112 penetrates the passivation layer 101 and the insulating layer 102.

Wherein, the first electrode layer 105 electrically connects to the thin film transistor device layer 109 through the first via 111. The third electrode layer 103 electrically connects to the metal wire layer 110 through the second via 112, in order to transmit data and control signals of the display panel.

The display panel further comprises a pixel defining layer 108, the pixel defining layer 108 is disposed on film layers corresponding to the display area AA of the display panel. Meanwhile, a plurality of pixel opening are provided in the pixel defining layer 108, and the composite electrode layer is disposed in the corresponding pixel opening areas.

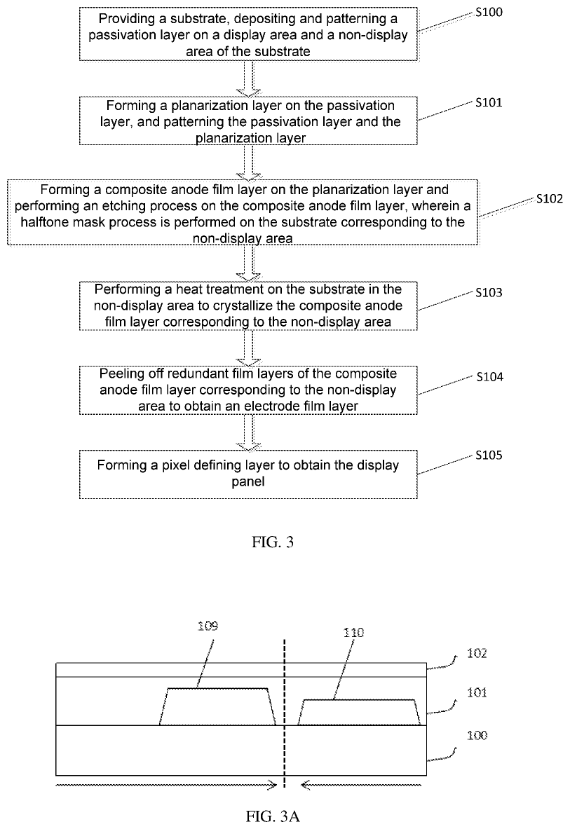

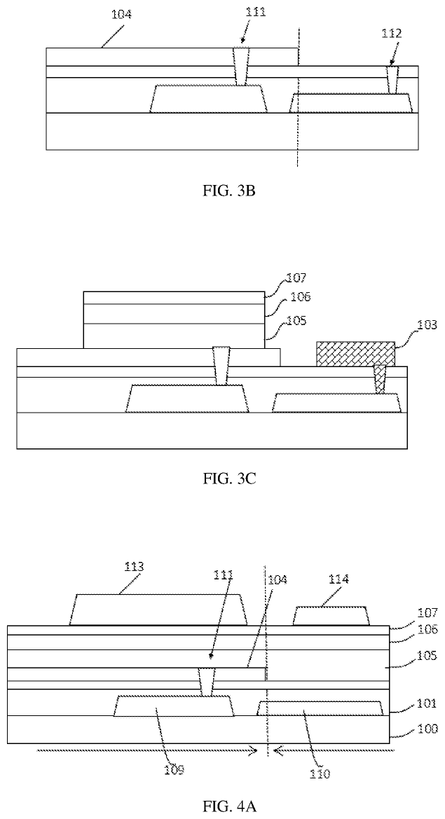

In addition, an embodiment of the present disclosure further provides a manufacturing method of a display panel, as shown in FIG. 3 in detail, the manufacturing method comprises the following steps:

S100: providing a substrate, depositing and patterning a passivation layer on a display area and a non-display area of the substrate.

S101: forming a planarization layer on the passivation layer and patterning the passivation layer and the planarization layer.

As shown in FIG. 3A and FIG. 3B, FIG. 3A and FIG. 3B are schematic structural diagram of film layers corresponding to the manufacturing method provided in an embodiment of the present disclosure. A substrate 100 is provided, and the substrate 100 may be an array substrate. A thin film transistor device layer 109 is formed in the display area corresponding to the substrate 100, and a metal wire layer 110 is formed in an area corresponding to the non-display area.

Meanwhile, a passivation layer 101 is formed on the substrate 100, and the passivation layer 101 covers the thin film transistor device layer 109 and the metal wire layer 110 entirely.

Furthermore, an insulating layer 102 is formed on the passivation layer 101, wherein materials of the insulating layer 102 is SiNx, preferably, a thickness of the SiNx film layer ranges from 5 nm to 500 nm.

A planarization layer 104 is formed on the insulating layer 102, and the planarization layer 104 is disposed on the area corresponding to the display area of the display panel.

After the above film layers are formed, corresponding film layers are patterned to form a first via and a second via.

In an embodiment of the present disclosure, in the step S100 and the step S101, a halftone mask may be used to pattern the corresponding film layers, in order to form the required film layer structure.

S102: forming and etching a composite anode film layer on the planarization layer, wherein a halftone mask process is performed on the substrate corresponding to the non-display area.

Corresponding electrode layers are formed continually. As shown in FIG. 3C, the composite anode film layer is disposed on the planarization layer of the display panel. Specifically, the composite anode film layer comprises a first electrode layer 105, a silver layer 106, and a second electrode layer 107 disposed in sequence.

After the composite anode film layer is disposed, the halftone mask process is performed on the composite anode film layer. The halftone mask process is performed on the corresponding composite anode film layer in the non-display area of the display panel to etch the silver layer 106 and the second electrode layer 107, only the first electrode film layer is left and the redundant photoresist layer is peeled off. Wherein, the photoresist layer may be one of organic photoresists such as polyimide series or acrylic series.

S103: performing a heat treatment on the substrate in the non-display area to crystallize the composite anode film layer corresponding to the non-display area.

S104: peeling off redundant film layers of the composite anode film layer corresponding to the non-display area to obtain an electrode film layer.

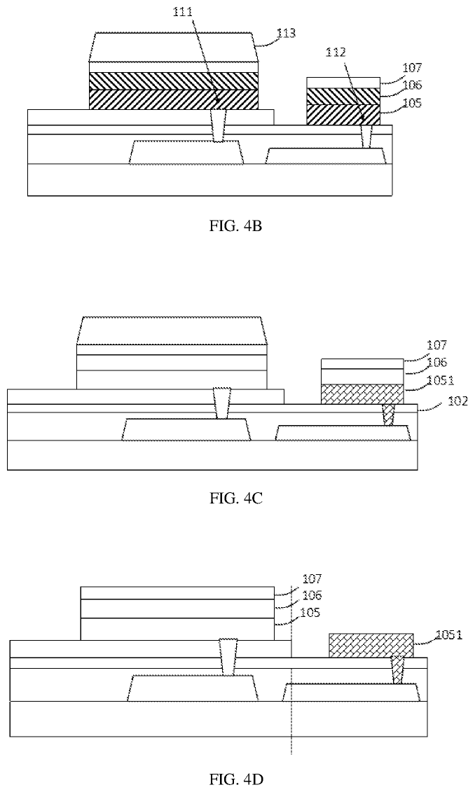

Particularly, as shown in FIGS. 4A-4D, FIG. 4A to FIG. 4D are schematic flowcharts of manufacturing process of the composite anode film layer provided in the embodiment of the present disclosure. As shown in FIG. 4A, after the film layers of the display panel are formed, the halftone mask process is performed on the display panel.

Meanwhile, refer to schematic structural diagrams of film layers shown in FIG. 2 and FIG. 3. In the embodiment of the present disclosure, the first electrode layer 105, the silver layer 106, and the second electrode layer 107 are disposed on the planarization layer 104 in sequence. At the same time, a first photoresist layer 113 is disposed on the second electrode layer 107 corresponding to the display area. Preferably, a thickness of the second electrode layer 107 is 20 nm to 110 nm, and the first electrode layer 105 and the second electrode layer 107 may both be indium tin oxide film layers, and a second photoresist layer 114 is disposed on the second electrode layer 107 corresponding to the non-display area.

The first photoresist layer 113 and the second photoresist layer 114 may be organic photoresist, specifically, is one of organic photoresists such as polyimide or acrylic, and at the same time, the photoresist may have better hydrophobic properties.

In addition, when etching the display panel, a halftone mask process is used, that is, the halftone mask process is performed on an area corresponding to the second photoresist layer 114 to etch out electrode layer patterns corresponding to respective areas.

The schematic diagram of structural film layers shown in FIG. 4B are obtained after etching. Continue to perform processes on corresponding electrode layers in the non-display area.

As shown in FIG. 4C, the first electrode layer 105 in the non-display area is crystallized by low-temperature baking to form a crystallized electrode layer 1051. Wherein, when the heat treatment is performed, the heat treatment can be performed under a temperature ranging from 100° C. to 150° C. and under protection of protecting gases.

The protecting gases may comprise O2, N2, air, or the heat treatment may be directly performed in a vacuum environment. Crystal grains in the crystallized electrode layer 1051 are finer. Therefore, after the insulating layer 102 is bonded, the bonding performance is better and not easy to fall off.

After the heat treatment is completed, continue to perform processes on the electrode layer. As shown in FIG. 4D, the unprocessed electrode layers in the halftone mask process are peeled off. That is, the second electrode layer 107 and the silver layer 106 in the non-display area are peeled off, and different electrode layer patterns are formed in different areas.

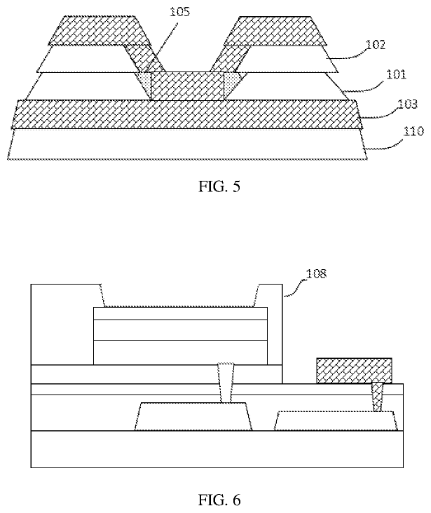

As shown in FIG. 5, FIG. 5 is a schematic diagram of a crystallized first electrode layer provided in an embodiment of the present disclosure. In the non-display area, the film layers comprise the metal wire layer 110, the third electrode layer 103, the passivation layer 101, the insulating layer 102, and part of the first electrode layer 105 that is not heat-treated completely disposed in sequence.

The third electrode layer 103 is disposed on the metal wire layer 110 corresponding to the non-display area of the display panel correspondingly, and electrically connects to the metal wire layer 110 through the via structure. After the heat treatment, the internal crystal grains of the material of the third electrode layer 103 are recrystallized and refined, thereby enhancing adhesion between the third electrode layer 103 and the metal wire layer 110, and the passivation layer 101, and the insulating layer 102.

S105: forming a pixel defining layer to obtain the display panel.

As shown in FIG. 6, FIG. 6 is a schematic structural diagram of a film layer structure of another display panel provided in an embodiment of the present disclosure. After the electrode layers are formed, the pixel defining layer 108 is formed on the film layers corresponding to the display area. At the same time, the electrode layers in the above area is disposed in an opening area of the pixel defining layer 108, and finally the display panel provided in the embodiment of the present disclosure is formed.

Preferably, in the above-mentioned processes, the method of patterning each film layer and the process of the via structure may comprise photoresist coating, exposure, development, etc., but is not limited to the above processes. Meanwhile, the manufacturing method provided in the embodiments of the present disclosure can be applied to top-emission mode type AMOLED panels obtained by vapor deposition or inkjet printing.

The display panel and the manufacturing method of the display panel provided in the embodiments of the present disclosure are described in detail above. The description of the above embodiments is only used to help understand the technical solutions and core ideas of the present disclosure; those of ordinary skill in the art should understand that it is still possible to modify the technical solutions recorded in the foregoing embodiments, and these modifications or replacements do not cause the essence of the corresponding technical solutions to deviate from the scope of the technical solutions of the embodiments of the present disclosure.

What is claimed is:

1. A manufacturing method of a display panel, comprising following steps:
S100: providing a substrate, and depositing and patterning a passivation layer on a display area and a non-display area of the substrate;
S101: forming a planarization layer on the passivation layer, and patterning the passivation layer and the planarization layer;
S102: forming a composite anode film layer on the planarization layer and performing an etching process on the composite anode film layer, the composite anode film layer comprises a first electrode layer, a silver layer, and a second electrode layer disposed in sequence, wherein a halftone mask process is performed on the substrate corresponding to the non-display area;
S103: performing a heat treatment on the substrate in the non-display area, the heat treatment is performed under a temperature ranging from 100° C. to 150° C. and under protection of protecting gases to crystallize the composite anode film layer corresponding to the non-display area;
S104: peeling off redundant film layers of the composite anode film layer corresponding to the non-display area to obtain an electrode film layer; and
S105: forming a pixel defining layer to obtain the display panel.

2. The manufacturing method of the display panel of claim 1, wherein the step S102 further comprises: performing a photoetching process on the substrate corresponding to the display area and the non-display area while using the halftone mask process.

3. The manufacturing method of the display panel of claim 2, wherein a mask corresponding to the non-display area is a semi-transmissive mask.

4. The manufacturing method of the display panel of claim 1, wherein when forming the composite anode film layer, the first electrode layer is disposed on the planarization layer.

5. The manufacturing method of the display panel of claim 4, wherein the first electrode layer electrically connects to thin film transistors and metal wires in the display panel through vias.

6. The manufacturing method of the display panel of claim 1, wherein in the step S100, when forming the passivation layer, a film layer on a side of the passivation layer away from the substrate is a SiNx film layer, and a thickness of the SiNx film layer ranges from 5 nm to 500 nm.

7. A manufacturing method of a display panel, comprising following steps:
S100: providing a substrate, and depositing and patterning a passivation layer on a display area and a non-display area of the substrate;
S101: forming a planarization layer on the passivation layer, and patterning the passivation layer and the planarization layer;
S102: forming a composite anode film layer on the planarization layer and performing an etching process on the composite anode film layer, wherein a halftone mask process is performed on the substrate corresponding to the non-display area;
S103: performing a heat treatment on the substrate in the non-display area to crystallize the composite anode film layer corresponding to the non-display area;
S104: peeling off redundant film layers of the composite anode film layer corresponding to the non-display area to obtain an electrode film layer; and
S105: forming a pixel defining layer to obtain the display panel.

8. The manufacturing method of the display panel of claim 7, wherein the step S102 further comprises: performing a photoetching process on the substrate corresponding to the display area and the non-display area while using the halftone mask process.

9. The manufacturing method of the display panel of claim 8, wherein a mask corresponding to the non-display area is a semi-transmissive mask.

10. The manufacturing method of the display panel of claim 7, wherein in the step S103, the treatment process comprises: performing the heat treatment under a temperature ranging from 100° C. to 150° C. and under protection of protecting gases.

11. The manufacturing method of the display panel of claim 7, wherein when forming the composite anode film layer, the composite anode film layer comprises a first electrode layer, a silver layer, and a second electrode layer disposed in sequence, and the first electrode layer is disposed on the planarization layer.

12. The manufacturing method of the display panel of claim 11, wherein the first electrode layer electrically connects to thin film transistors and metal wires in the display panel through vias.

13. The manufacturing method of the display panel of claim 7, wherein in the step S100, when forming the passivation layer, a film layer on a side of the passivation layer away from the substrate is a SiNx film layer, and a thickness of the SiNx film layer ranges from 5 nm to 500 nm.

14. A display panel, wherein the display panel comprises a display area and a non-display area around the display area, and the display panel comprises:
a substrate;
a passivation layer disposed on the substrate;
a planarization layer disposed on the passivation layer corresponding to the display area; and
a pixel defining layer disposed on the passivation layer corresponding to the display area;
wherein the display panel further comprises a composite anode film layer and a first electrode layer, the composite anode film layer is disposed in a pixel opening area corresponding to the pixel defining layer, and the first electrode layer is disposed on the passivation layer corresponding to the non-display area, wherein the composite anode film layer electrically connects to thin film transistors through first vias, and the first electrode layer electrically connects to metal wires in the substrate through second vias.

15. The display panel of claim 14, wherein the composite anode film layer comprises an indium tin oxide film layer, a silver layer, and a second electrode layer, and the silver layer is disposed on the indium tin oxide film layer.

16. The display panel of claim 14, wherein the first electrode layer comprises a crystallized indium tin oxide film layer.

17. The display panel of claim 14, wherein material of the passivation layer comprises SiO2, SiNx, Al2O3.

18. The display panel of claim 17, wherein the material of the passivation layer is SiNx, and a thickness of the passivation layer ranges from 5 nm to 500 nm.

19. The display panel of claim 14, wherein the display panel further comprises the metal wires, and the metal wires are disposed in the non-display area of the display panel.

20. The display panel of claim 19, wherein material of the metal wires comprises Mo, Al, Ti, Cu.
